(19) United States
(12) Patent Application Publication
(10) Pub. No.: US 2026/0351966 A1
(43) Pub. Date: Nov. 5, 2026

(54) FEED FORWARD TRANSIENT ASSIST MODE IN MICROGRID CONTROLLER

(71) Applicant: Caterpillar Inc., Peoria, IL (US)

(72) Inventors: Sowmya NAGESH, Peoria, IL (US); Gregory Scott HASLER, Pekin, IL (US); Bradley Paul OHLROGGE, Peoria, IL (US); Kevin J. SERGOTT, Dunlap, IL (US); Ronald Christopher GAYLES, Peoria, IL (US)

(73) Assignee: Caterpillar Inc., Peoria, IL (US)

(21) Appl. No.: 19/194,536

(22) Filed: Apr. 30, 2025

(51) Int. Cl. H02J 3/0012; H03K 3/017

(52) U.S. Cl. CPC H02J 3/0012; H03K 3/017

(57) ABSTRACT

A microgrid controller of a microgrid is configured to communicate with a plurality of energy resource systems and a plurality of loads via a first communication interface, the first communication interface being a message-based communication interface; communicate with inverter-based energy resource systems via a second communication interface, the second communication interface being a pulse-width modulation (PWM)-based communication interface; monitor a total load for load transients based on one or more load parameters measured by a power meter; detect a fast load transient of the total load that satisfies a transient threshold of one or more transient thresholds; generate, based on detecting the fast load transient, a PWM control signal; and transmit, via the second communication interface, the PWM control signal to at least one inverter-based energy resource system of the inverter-based energy resource systems to satisfy a transient total load corresponding to the fast load transient.

### TECHNICAL FIELD

The present disclosure relates generally to microgrids and, for example, to a microgrid controller configured to control or manage an operation of a microgrid.

### BACKGROUND

A microgrid is a self-sufficient energy system that serves a particular geographic area, such as a college campus, a hospital complex, a business center, a neighborhood, a mining site, a drilling site, and/or the like. Within a microgrid are one or more kinds of distributed energy resources (DERs) (e.g., solar panels, wind turbines, fuel cells, photovoltaic (PV) cells, generators, energy storage devices (e.g., batteries, capacitors), and/or other energy sources) that produce power for the microgrid. Some microgrids are configured as off-grid electrical power distribution systems (e.g., stand-alone microgrids or islands) that do not connect to a larger electrical power distribution system (e.g., a macrogrid) run by, for example, an electric utility or power plant. Some microgrids are able to operate in a grid-connected mode and/or in a stand-alone mode. In a grid-connected mode, a microgrid may operate connected to and synchronous with the larger electrical power distribution system. In a stand-alone mode, the microgrid may be disconnected from the larger electrical power distribution system and operate as a stand-alone microgrid. A microgrid controller may control whether the microgrid operates in the grid-connected mode or in the stand-alone mode, for example, based on a schedule or based on one or more conditions being satisfied.

A recurrence of frequency deviations on a microgrid may be caused by repetitive load steps produced by one or more non-stable loads, such as one or more cyclic loads. For example, cyclic loads may be produced at mine sites or oil rigs where crushers or industrial drills may be used over short bursts of time. A total load increases on a microgrid when non-stable loads come online periodically. The increase in the total load causes a frequency deviation on the microgrid from a nominal value, and a power quality provided by the microgrid is reduced. In addition, non-stable loads may cause fast transient loads. In other words, a total load demand on the microgrid may change very quickly, requiring fast dispatching (e.g., power increase or decrease) of DERs to satisfy a transient total load. Typically, microgrid controller or an energy management system (EMS) are not able to dispatch fast transient loads using inverter-type DERs, such as battery energy storage systems (BESS).

U.S. Pat. No. 10,498,155 (“the '155 patent”) discloses a system for controlling a battery state-of-energy within a microgrid. The system includes an energy generation (EG) system, an electrical load coupled to the EG system, an energy storage system coupled to the EG system and the electrical load, and a controller coupled to the EG system and the energy storage system. The energy storage system can charge and discharge according to a target charge value and a target discharge value, which may be based on a state-of-energy of the energy storage system. The controller can control a power generation of the EG system based on the load demand and the target charge value and target discharge value of the energy storage system. The controller can further control a power generation of a second EG system when the EG system cannot meet the load demand and maintain the state-of-energy of the energy storage system within a desired level. However, according to the '155 patent, battery energy storage is required to be dispatched within state of charge or state of energy thresholds to optimize performance and longevity.

The microgrid system of the present disclosure solves one or more of the problems set forth above and/or other problems in the art.

### SUMMARY

A microgrid system may include a plurality of energy resource systems configured to supply power to a microgrid, wherein the plurality of energy resource systems includes inverter-based energy resource systems; a plurality of loads coupled at a common coupling; one or more power buses configured to deliver power from the plurality of energy resource systems to the plurality of loads; a power meter coupled to the common coupling and configured to measure, at the common coupling, one or more load parameters corresponding to a total load required by the plurality of loads; and a microgrid controller configured to: communicate with the plurality of energy resource systems and the plurality of loads via a first communication interface, the first communication interface being a message-based communication interface, communicate with the inverter-based energy resource systems via a second communication interface, the second communication interface being a pulse-width modulation (PWM)-based communication interface, monitor the total load for load transients based on the one or more load parameters measured by the power meter, detect a fast load transient of the total load that satisfies a transient threshold of one or more transient thresholds, generate, based on detecting the fast load transient, a PWM control signal, and transmit, via the second communication interface, the PWM control signal to at least one inverter-based energy resource system of the inverter-based energy resource systems to satisfy a transient total load corresponding to the fast load transient.

A microgrid controller of a microgrid may include a message-based communication interface configured to enable message-based communications with a plurality of loads connected to the microgrid and a plurality of energy resource systems connected to the microgrid, wherein the plurality of energy resource systems includes inverter-based energy resource systems; a PWM-based communication interface configured to transmit PWM commands to the inverter-based energy resource systems; a third communication interface configured to receive, from a power meter coupled to a common coupling of the plurality of loads, one or more load parameters corresponding to a total load required by the plurality of loads; one or more memories; and one or more processors, coupled to the one or more memories, configured to: monitor the total load for load transients based on the one or more load parameters measured by the power meter, detect a fast load transient of the total load that satisfies a transient threshold of one or more transient thresholds, generate, based on detecting the fast load transient, a PWM control signal, and transmit, via the PWM-based communication interface, the PWM control signal to at least one inverter-based energy resource system of the inverter-based energy resource systems to satisfy a transient total load corresponding to the fast load transient.

A method for controlling assets of a microgrid may include receiving, by a microgrid controller of the microgrid, from a power meter coupled to a common coupling of a plurality of loads, one or more load parameters corresponding to a total load of the plurality of loads; monitoring, by the microgrid controller, the total load for load transients based on the one or more load parameters measured by the power meter; detecting, by the microgrid controller, a fast load transient of the total load that satisfies a transient threshold of one or more transient thresholds; generating, by the microgrid controller, based on detecting the fast load transient, a PWM control signal; and transmitting, by the microgrid controller, via a PWM-based communication interface, the PWM control signal to at least one inverter-based energy resource system of the inverter-based energy resource systems to satisfy a transient total load corresponding to the fast load transient.

### BRIEF DESCRIPTION OF THE DRAWINGS

FIG. 1 shows a system according to one or more implementations.

FIG. 2 shows a microgrid according to one or more implementations.

FIG. 3 shows a microgrid according to one or more implementations.

FIG. 4 is a flowchart of an example process associated with a feed forward transient assist mode in a microgrid controller.

FIG. 5 is a diagram of example components of the microgrid controller associated with a feed forward transient assist mode.

### DETAILED DESCRIPTION

This disclosure relates to a power distribution system, and is applicable to any system that distributes and/or receives power via a power grid. Some aspects relate to a microgrid controller that is configured to control one or more components and/or systems associated with the microgrid, including energy resource systems and/or loads. The microgrid controller may control a state of the microgrid based on one or more conditions being satisfied.

Many microgrid systems do not have an efficient way to adequately handle fast load transients, including a dispatching of DERS to quickly satisfy load demands that follow a fast transient. Large cyclic loads tend to produce fast load transients that result in a transient total load on the microgrid system that changes over time. A message-based communication interface, such as a transmission control protocol (TCP) communication bus and/or a communication interface that uses a Modbus communication protocol, is typically too slow to convey load information, from loads to a microgrid controller, and dispatch commands, from the microgrid controller to DERs, to adequately address fast load transients. For example, messages of a message-based communication interface require processing time, including processing time for packetization, depacketization, serialization, deserialization, framing, encoding, decoding, message queuing, error detection and correction, etc.

Some implementations disclosed herein provide a microgrid system that includes a microgrid controller (or energy management system) that has a fast dispatch mode to handle fast load transients for satisfying transient total loads. The fast dispatch mode may incorporate a feed forward control scheme. Using the fast dispatch mode, the microgrid controller is able to dispatch transient loads using battery energy storage systems or similar inverter-based DERs in multiple configurations. Accordingly, the microgrid controller may drive the dispatching of transient loads in real time (e.g., a real-time dispatch mode) using a fast communication interface (e.g., analog voltage, analog current, PWM, or dry contact) to turn on/off inverter-based DERs. For example, the microgrid controller may use a dry contact to turn on or otherwise discharge battery energy storage systems, or to turn off or otherwise charge the battery energy storage systems. In some implementations, the microgrid controller may have a mode of operation allowing for fast discharge and fast charge of the battery energy storage systems using current control. The mode of operation is applicable to all bidirectional inverter configurations, such as string, redundant two-stage or three-stage hybrid inverters, etc. The microgrid controller may be configured to transmit commands, such as PWM commands, to an inverter controller or a battery rack controller to allow for charging and discharging dispatching in real time. Put another way, the microgrid controller may be configured to transmit commands to a local controller of a DER or a group of DERs to enable or disable power dispatch from the DER or the group of DERs. When enabled for power dispatch, the DER or the group of DERs may supply power to the loads to satisfy the transient total load. Conversely, when disabled for power dispatch, the DER or the group of DERs may halt supplying power to the loads to satisfy the transient total load, and may additionally absorb power from the microgrid. For battery energy storage systems, supplying power may correspond to a discharging state, and absorbing power may correspond to a charging state.

The fast dispatch mode may be useful where multiple types of loads have to be added to the microgrid or shed from the microgrid. The fast dispatch mode may be optimized in microgrid systems where there are multiple utility feeders and BESS-based DERs have to be brought online in an emergency tie-based configuration, which may be based on peak loads.

Accordingly, some implementations provide transient load management for microgrid controllers. An additional mode of operation allows for fast discharge and charge of a BESS using current control and sends commands to inverter controllers or battery rack controllers for real-time charge and discharge.

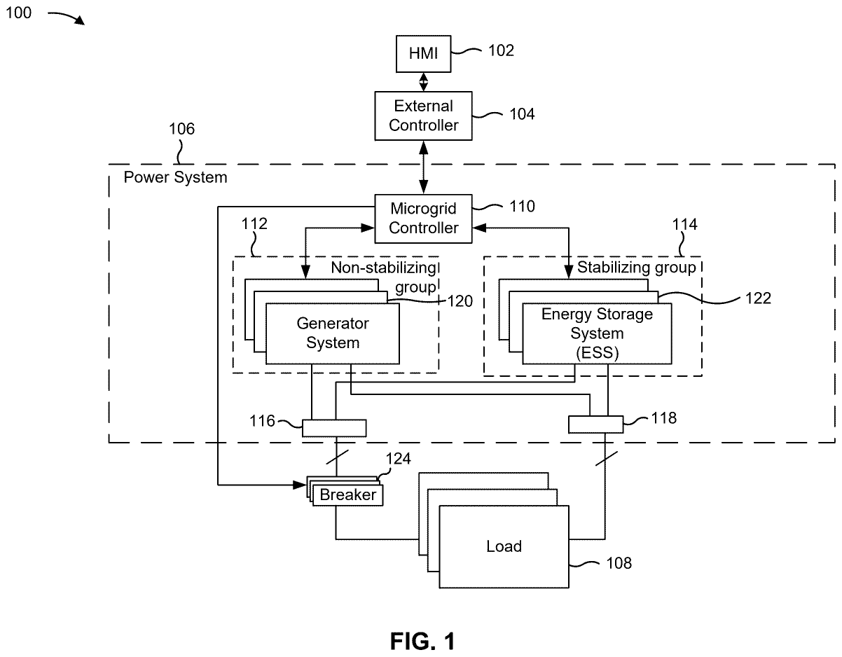

FIG. 1 shows a system 100 according to one or more implementations. The system 100 may include a human-machine interface (HMI) 102, an external controller 104, a power system 106, and one or more loads 108.

The power system 106 may be a microgrid or other type of electrical power distribution system that may provide power to the one or more loads 108. In some cases, the power system 106 may be an off-grid electrical power distribution system. In some cases, the power system 106 may be configurable to operate in a grid-connected mode and in a stand-alone mode. The power system 106 may include a microgrid controller 110, a non-stabilizing group of energy resource systems 112 (e.g., a non-stabilizing group of DERs), a stabilizing group of energy resource systems 114 (e.g., a stabilizing group of DERs), and interfaces 116 and 118. Generally, “off-grid” may mean that the electrical power distribution system is not connected to a larger electrical power distribution system run by, for example, an electric utility or other large-scale electric power generation plant that serves electricity to a geographic area, campus, compound, etc. However, techniques disclosed herein may still be applied to electrical power distribution systems that are connected to larger electrical power distribution systems. For instance, the larger electrical power distribution systems may operate as a power source in a primary provider role or secondary provider role, while the power system 106 may operate as a power source in the other of the primary provider role or secondary provider role.

The non-stabilizing group of energy resource systems 112 may include one or more energy generator systems 120. Each energy generator system 120 may include a power generator (e.g., an engine-generator, a fuel cell, a PV cell, or other power generating system) and a local generator controller communicatively coupled to the microgrid controller 110. Thus, each energy generator system 120 may generate power from a respective power source. Each local generator controller may control how much power a respective power generator generates, control a rate of power distribution, and/or obtain status information corresponding to the respective power generator. Each local generator controller may be controlled by the microgrid controller 110.

The stabilizing group of energy resource systems 114 may include one or more energy storage systems (ESSs) 122. Each energy storage system 122 may include an electric storage device (e.g., one or more batteries and/or capacitors) and a local ESS controller communicatively coupled to the microgrid controller 110. Each local ESS controller may control a flow of power into or out of a respective electric storage device, including charging of the respective electric storage device and discharging of the respective electric storage device, control a rate of power flow, and/or obtain status information corresponding to the respective electric storage device, such as state-of-charge (SOC), state-of-health (SOH), discharge limit, and other device parameters. Each local ESS controller may be controlled by the microgrid controller 110.

The system 100 may also include one or more breakers 124 (e.g., distribution breakers or switches) that may be individually controlled by the microgrid controller 110 to connect a respective load 108 to the power system 106 or disconnect the respective load 108 from the power system 106. The one or more breakers 124 may be part of one or both interfaces 116 and 118.

The HMI 102 may include one or more processors, and may be configured to receive and process one or more inputs from a user, such as an operator. Additionally, the HMI 102 may be configured to provide one or more prompts or outputs to the user. Thus, the HMI 102 may be a user terminal configured to interact with a user to process information and/or commands provided by the user, provide information to the user (e.g., status information), and/or perform one or more tasks or functions in response to processing the information and/or commands provided by the user. The HMI 102 may be communicatively coupled to the external controller 104, which may be communicatively coupled to the microgrid controller 110. In some implementations, the HMI 102 may be communicatively coupled directly to the microgrid controller 110. The external controller 104 may send commands to and receive information from the microgrid controller 110. For example, the external controller 104 may send commands to the microgrid controller 110 based on information received from the HMI 102. Thus, the external controller 104 may be a user-commanded controller. The external controller 104 may be integrated with the HMI 102. The external controller 104 may be a controller of a larger electrical power distribution system (e.g., a macrogrid, a power generation plant, and/or electric utility provider).

The power system 106 may provide electrical power to the one or more loads 108. Generally, the power system 106 may provide alternating current (AC) power at a particular voltage and a particular current. The microgrid controller 110 may control one or more energy storage systems 122 to instantaneously inject power when power is needed by the power system 106 or instantaneously absorb surplus power generated by the power system 106. Accordingly, one of more electric storage devices of the energy storage systems 122 may act as a power consumer on one or more energy generator systems 120 or as a power source for the one or more energy generator systems 120, to thereby ensure that system bus frequencies of the non-stabilizing group of energy resource systems 112 are maintained at a nominal value. In other words, the microgrid controller 110 may control the stabilizing group of energy resource systems 114 to stabilize loads of the non-stabilizing group of energy resource systems 112 in order to maintain the non-stabilizing group of energy resource systems 112 at a relatively constant load, which may reduce a recurrence of frequency deviations from the nominal value.

The microgrid controller 110 may be integrated with, or separate from (but connected to), the interfaces 116 and 118, the energy generator systems 120, and the energy storage systems 122, or combinations thereof. In this manner, a user may, through interaction with the HMI 102, add or remove energy generator systems 120 to increase/reduce system power generation and/or add or remove energy storage systems 122 to increase/reduce system energy storage capacity, in accordance with a user's preference. For instance, a user may prefer to add additional energy generator systems 120 and/or add additional energy storage systems 122 to increase load capacity if additional loads 108 are expected to be connected to the power system 106, or remove energy generator systems 120 and/or remove energy storage systems 122 to decrease load capacity if loads 108 are expected to be disconnected from the power system 106. Additionally, the microgrid controller 110 may be configured to add or remove energy generator systems 120 and/or add or remove energy storage systems 122 from the power system 106 based one or more conditions being satisfied. In some cases, the microgrid controller 110 may be configured to add or remove energy generator systems 120 and/or add or remove energy storage systems 122 from the power system 106 based on a schedule.

The one or more loads 108 may be any device that can connect to a power distribution system, such as the power system 106, to receive electrical power. Examples of loads may include heavy machinery (e.g., electric mining machines, haulers, etc.), personal devices, appliances, heating, ventilation, and air conditioning (HVAC) systems, industrial drills, personal residence electrical distribution systems, etc. The loads 108 may include one or more non-stable loads, such as one or more cyclic loads. The loads 108 may include unidirectional loads (e.g., loads that can only receive power from the power system 106), bi-directional loads (e.g., loads that can both receive power from the power system 106 and provide power to the power system 106), charging loads (e.g., loads that include a chargeable electric battery), essential loads (e.g., loads that require uninterrupted service), and/or non-essential loads (e.g., loads that do not require uninterrupted service). Loads may be assigned different priorities based on load type, load classification, and/or operation state or mode.

Generally, the one or more loads 108 may receive the power from the power system 106 and use the power in accordance with the operations of the one or more loads 108. Users of the power system 106 and the one or more loads 108 may connect/disconnect the one or more loads 108 by electrically connecting the one or more loads 108 to the interfaces 116 and 118 of the power system 106. For instance, the interfaces 116 and 118 may have AC plugs/sockets to connect the one or more loads 108 in parallel to the one or more energy generator systems 120 and the one or more energy storage systems 122 of the power system 106. One or more loads 108 may include a local load controller that may collect load information and transmit the load information to the microgrid controller 110. Load information may include information indicating a load type, a load classification, and/or an operation state or mode of a load 108. The loads can be active (real) or reactive to allow for a power quality-based approach to scheduling. Load information may include load data of a load, such as maximum load and minimum load. For chargeable loads, load information may include maximum charging load, maximum state of charge, minimum state of charge, current state of charge, and usable discharge energy as a function of the current state of charge. Load information may be received by the microgrid controller 110 via the interfaces 116 and 118, which may include one or more communication interfaces coupled to the microgrid controller 110.

The interfaces 116 and 118 may also have a plurality of generator connections and a plurality of energy store connections. The plurality of generator connections may be hardwired electrical connections and/or AC plugs/sockets to connect the one or more energy generator systems 120 in parallel to the at least one load 108 and the one or more energy storage systems 122. The plurality of energy store connections may be hardwired electrical connections and/or AC plugs/sockets to connect the one or more energy storage systems 122 in parallel to the one or more loads 108 and the one or more energy generator systems 120. For instance, the power system 106 may or may not allow addition/removal of energy generator systems 120 and/or addition/removal of energy storage systems 122. Therefore, depending on a configuration, the interfaces 116 and 118 may include: (1) hardwired electrical connections that connect the at least one energy generator system 120; (2) AC plugs/sockets to connect/disconnect the at least one energy generator system 120; (3) hardwired electrical connections that connect the at least one energy storage system 122; and/or (4) AC plugs/sockets to connect/disconnect the at least one energy storage system 122. The interfaces 116 and 118 may be coupled to a system bus (e.g., a power bus) of the power system 106. The system bus may enable one of more of the energy storage systems 122 to absorb power from one or more energy generator systems 120 and/or one or more loads 108 (e.g., for charging and/or storing power).

The one or more energy generator systems 120 may also include communication interfaces. The communication interfaces of the one or more energy generator systems 120 may enable the one or more energy generator systems 120 to communicate with the microgrid controller 110. For instance, the one or more energy generator systems 120 may be connected to the microgrid controller 110 by wired or wireless communication. The one or more energy generator systems 120 may provide the microgrid controller 110 with generator data (e.g., energy resource information). The generator data, for each of the one or more energy generator systems 120, may include load data and/or generator parameters. The load data may include a current (e.g., instantaneous) load seen by the one or more energy generator systems 120 and/or past load data (if one or more energy generator systems 120 store such data locally). The current load/past load data may include voltage (e.g., in volts) and/or current (e.g., in amperes) measured by one or more sensor components included in an energy generator system 120. The generator parameters may include a generator set maximum threshold value and a generator set minimum threshold value. Alternatively, to reduce transmission bandwidth, the generator data may omit the generator parameters, and the one or more energy generator systems 120 may transmit the generator parameters during an initial configuration process between the one or more energy generator systems 120 and the microgrid controller 110. The generator set maximum threshold value and the generator set minimum threshold value may indicate a maximum power load and a minimum power load, respectively, that a generator of an energy generator system 120 may support.

The one or more energy storage systems 122 may be any energy storage device that can store and output AC power. For instance, the one or more energy storage systems 122 may include at least one electrical-chemical energy storage (e.g., a battery), electrical energy storage (e.g., a capacitor, a supercapacitor, or a superconducting magnetic energy storage), mechanical energy storage (e.g., a fly wheel, a pump system), and/or any combination thereof. The one or more energy storage systems 122 may include inverters (individually or collectively) so that the one or more energy storage systems 122 may operate as a power consumer or a power source. The one or more energy storage systems 122 may also include electronic control mechanisms to control (1) how much load the one or more energy storage systems 122 draw, or (2) how much AC power the one or more energy storage systems 122 output.

The one or more energy storage systems 122 may also include communication interfaces. The communication interfaces of the one or more energy generator systems 120 may enable the one or more energy storage systems 122 to communicate with the microgrid controller 110. For instance, the one or more energy storage systems 122 may be connected to the microgrid controller 110 by wired or wireless communication. The one or more energy storage systems 122 may provide the microgrid controller 110 with energy storage data (e.g., energy resource information) and may receive instructions from the microgrid controller 110.

The energy storage data may include, for each of the at least one energy store, a current energy level (e.g., kilowatt-hours currently stored), total energy storage capacity (e.g., kilowatt-hours of capacity), and/or discharge/charge parameters. The current energy level may be measured by a battery meter of an energy storage. The battery meter may one or combinations of a voltmeter, an amp-hour meter, and/or an impedance-based meter. The discharge/charge parameters may indicate an amount of discharge power and an amount of charge power for a respective energy storage device of the one or more energy storage systems 122. Alternatively, to reduce transmission bandwidth, the energy storage data may omit the discharge/charge parameters, and the one or more energy storage systems 122 may transmit the discharge/charge parameters when the one or more energy storage systems 122 are first connected to the microgrid controller 110.

The one or more energy storage systems 122 may receive requests (e.g., instructions) for the energy storage data to provide the energy storage data and/or continuously provide the energy storage data to the microgrid controller 110. The instructions may include energy storage dispatch (ESD) instructions. An ESD instruction may include an instruction to inject power to a system bus of the power system 106 or absorb power from the system bus of the power system 106. ESD instructions may be provided in control signals (e.g., communication signals that provide the ESD instructions). At least one ESD instruction may be utilized to rapidly stabilize the load, thereby stabilizing the bus frequency of the power system 106 in a time efficient manner, rather than attempting to stabilize the load using the one or more energy generator systems 120 alone. The one or more energy storage systems 122 may control the inverters and the electronic control mechanisms to control (1) quantity of load drawn by the one or more energy storage systems 122, or (2) the amount of AC power output produced by the one or more energy storage systems 122, in accordance with the ESD instructions. Reactive and/or active may be used as a qualifier for loads, where reactive loads may contribute to a stabilization algorithm in addition to the active or real loads.

The microgrid controller 110 may include at least one memory device (e.g., one or more memories) for storing instructions (e.g., program code); at least one processor for executing the instructions from the memory device to perform a set of desired operations; and a communication interface (e.g., coupled to a communication bus) for facilitating the communication between various system components. The instructions may be computer-readable instructions for executing a control application. The communication interface of the microgrid controller 110 may enable the microgrid controller 110 to communicate with the one or more energy generator systems 120 and the one or more energy storage systems 122. The microgrid controller 110, while executing the control application, may receive the generator data and the energy storage data (e.g., energy resource information), process the generator data and the energy storage data to generate one or more ESD instructions, and output the ESD instructions to one or more energy generator systems 120 and/or to one or more energy storage systems 122.

To process the generator data and the energy storage data to generate the ESD instructions, the control application may include a load stabilization function and/or an SOC function. The control application may also include a generator set limit function and/or energy store discharge/charge limit function to generate the ESD instruction. In some cases, the load stabilization function may be activated while the power system 106 is configured in stand-alone mode in order to provide off-grid load stabilization. The microgrid controller 110 may automatically activate or deactivate the aforementioned system functions based on a presence or an absence of system parameters (such as no generator set minimum threshold value being available, etc.) or one or more system conditions being satisfied.

Generally, the load stabilization function may ensure that system bus frequencies of the one or more energy generator systems 120 are maintained at a nominal value by causing an amount of power to be absorbed/injected by the one or more energy storage systems 122. The amount of power may be determined based on a difference from an instantaneous load and a moving average of the load. Meanwhile, the SOC function may ensure that the one or more energy storage systems 122 are charged to a target SOC or a target SOC range such that a SOC of one or more energy storage systems does not drift too low or too high, outside of a desired operating range (e.g., the target SOC range). The target SOC or the target SOC range may enable the at least one energy storage system 122 to provide long term beneficial use to the system 100, such as having a range of operation usable by the power system 106 and/or avoid degradation ranges of the one or more energy storage systems 122.

One or more energy generator systems 120 may include an engine-generator (e.g., a genset) that provides AC power to the power system 106, which may provide the AC power to the at least one load 108. Generally, an engine-generator may be any device that converts motive power (mechanical energy) into electrical power to output the AC power. An engine-generator may be a gas turbine electrical generator. In such gas turbine electrical generators, fast changes in load from the at least one load 108 may cause a system bus frequency to deviate from a nominal value. The system bus frequency may be a frequency of electrical components of the generator. For instance, such gas turbine electrical generators may have isochronous frequency control governors that may try to maintain the system bus frequency to the nominal value in response to changes of the load of the one or more loads 108. Therefore, during a transient load charge (e.g., a load transient), the system bus frequency may change as the load on the engine-generator changes. However, a rate of return of the system bus frequency back to the nominal value is slower than a desired rate due to an inertia of motion of physical components (e.g., a rotor of a stator-rotor) of the engine-generator. The slow rate of return may reduce power quality of the power system 106. The power quality of the power system 106 may be determined based on the voltage, frequency, and waveform of the power output to the one or more loads 108. A high power quality may ensure continuity of service for the one or more loads 108, such that the one or more loads 108 are able to properly function as intended. A low power quality may cause the one or more loads 108 to malfunction, fail prematurely, or not operate at all.

Therefore, avoiding load transients may be beneficial in providing better power quality. However, generally, controlling a load of the one or more loads 108 may not be possible or desirable. Instead, the microgrid controller 110 may control the one or more energy storage systems 122 of the stabilizing group of energy resource systems 114 to act as a power consumer or as an energy source, so that the one or more energy generator systems 120 of the non-stabilizing group of energy resource systems 112 may maintain the system bus frequency at the nominal value, thereby ensuring better power quality.

The microgrid controller 110 may control the one or more energy storage systems 122 to act as a near instantaneous load or energy source, so that the one or more energy generator systems 120 may maintain the system bus frequency at the nominal value, thereby ensuring better power quality. In one aspect of this disclosure, the microgrid controller 110 may control the one or more energy storage systems 122 to instantaneously inject power when power is needed by the at least one load 108 or instantaneously absorb surplus power generated by the one or more energy generator systems 120. Accordingly, the microgrid controller 110 regulates the power supply such that an exact amount of desired power supply flows in or out of the power system 106 at any given time. The instantaneous injecting/absorbing power may be performed to control the amount of transient load seen by the power system 106 and thus stabilize the load and resulting system bus frequency of the one or more energy generator systems 120. The desired power may be calculated by performing a moving average of a system load and then taking a difference of the moving average and an instantaneous load value. This difference may be the desired power output/absorbed of the energy store. Causing the one or more energy storage systems 122 to output/absorb the desired power (e.g., by transmitting the energy storage dispatch instructions) may limit the transient load seen by the one or more energy generator systems 120.

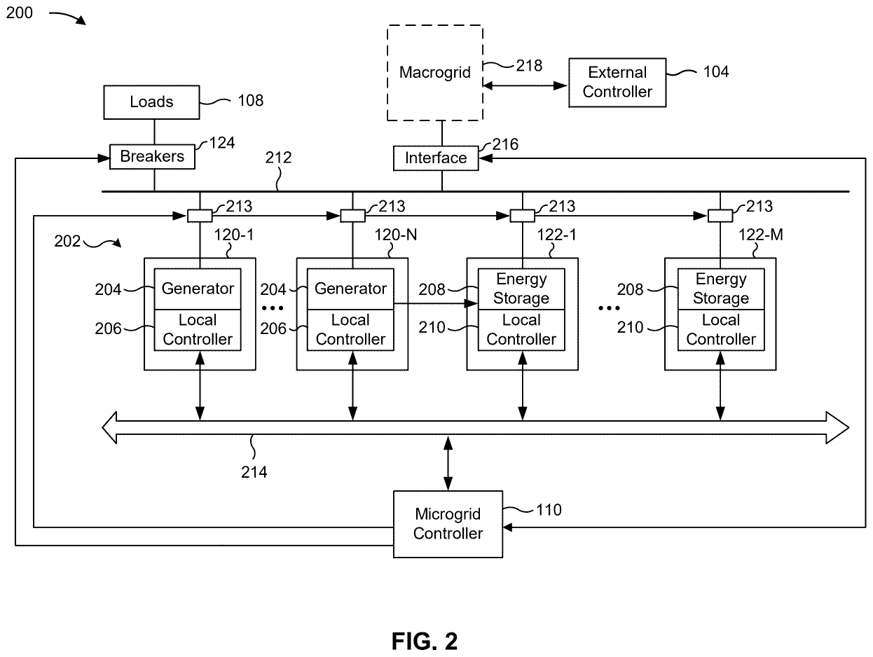

FIG. 2 shows a microgrid 200 according to one or more implementations. The microgrid 200 may be an example of the power system 106 described in connection with FIG. 1. The microgrid 200 may include a plurality of DERs 202. The plurality of DERs 202 may include N energy generator systems 120 and M energy storage systems 122, where N and M are integers greater than zero. For example, the plurality of DERs 202 may include a first energy generator system 120-1 and an N^{th} energy generator system 120-N. Additionally, the plurality of DERs 202 may include a first energy storage system 122-1 and an M^{th} energy storage system 122-M. Each energy generator system 120 may include a power generator 204 and a local generator controller 206. Each energy storage system 122 may include an electric storage device 208 (e.g., one or more batteries and/or capacitors) and a local ESS controller 210.

Each energy generator system 120 may be coupled to a power bus 212 for providing power to one or more loads connected to the power bus 212. Additionally, each energy storage system 122 may be coupled to the power bus 212 for providing power to or absorbing power from the power bus 212 (e.g., for providing power to or absorbing power from one or more components, such as one or more loads and/or one or more energy generator systems 120 connected to the power bus 212).

The microgrid 200 may also include the microgrid controller 110 that is communicatively coupled to the local controllers (e.g., local generator controllers 206 and local ESS controllers 210) of each DER 202 across a communication bus 214. The communication bus 214 may also enable the microgrid 200 to communicate with one or more loads and/or one or more load management systems (e.g., charging systems, fleet management systems, local load controllers, etc.). In some cases, two or more communication buses 214 may be provided. For example, one communication bus may be provided to communicate with local controllers and another communication bus may be provided to communicate with one or more loads and/or one or more load management systems.

Each local generator controller 206 may include any appropriate hardware, software, and/or firmware to sense and control a respective power generator 204, and send information to, and receive information, from microgrid controller 110. For example, a local generator controller 206 may be configured to sense, determine, and/or store generator data of its respective power generator 204. The generator data may be sensed, determined, and/or stored in any conventional manner. Each local generator controller 206 may control whether a respective power generator 204 is connected to or disconnected from the power bus 212 (for example, based on an instruction or a control signal received from the microgrid controller 110).

Each local ESS controller 210 may include any appropriate hardware, software, and/or firmware to sense and control a respective electric storage device 208, and send information to, and receive information, from microgrid controller 110. For example, a local ESS controller 210 may be configured to sense, determine, and/or store various characteristics of its respective electric storage device 208. Such characteristics of the respective electric storage device 208 may include, among others, a current SOC, a current energy, an SOC minimum threshold, an SOC maximum threshold, and a discharge limit of the respective electric storage device 208. These characteristics of each respective electric storage device 208 may be sensed, determined, and/or stored in any conventional manner. Each local ESS controller 210 may control whether a respective electric storage device 208 is connected to or disconnected from the power bus 212 (for example, based on an instruction or a control signal received from the microgrid controller 110).

The microgrid controller 110 may receive or determine a need for charging or discharging of power from the microgrid 200, and may be configured to determine and send signals to allocate a total charge request and/or total discharge request across all of the plurality of DERs 202.

When performing the power allocation functions, the microgrid controller 110 may allocate a certain amount of power from each energy generator system 120 to one or more loads 108. The one or more loads 108 may be connected to the power bus 212 via one or more breakers 124 to receive power from the power bus. When performing the power allocation functions, the microgrid controller 110 may allocate a total charge request and/or a total discharge request across the energy storage systems 122 as a function of a usable energy capacity of each energy storage system 122. The usable energy capacity corresponds to the capacity or amount of energy that an energy storage system 122 can receive in response to a total charging request (usable charge energy), or the capacity or amount of energy that an energy storage system can discharge in response to a total discharge request (usable discharge energy). The usable charge energy is a function of a maximum state of charge, current state of charge, and current energy of the energy storage system, and the usable discharge energy is a function of a minimum state of charge, and current energy of the energy storage system 122. The microgrid controller 110 may determine a usable charge/discharge capacity of each energy storage system 122 (e.g., SOC), a desired charge/discharge of each energy storage system 122, a remainder power of each energy storage system 122, and/or an SOH of each energy storage system 122.

Thus, the microgrid controller 110 regulates a power supply of the microgrid 200 such that an exact amount of desired power flows into or out of the power system 106 at any given time. The microgrid controller 110 may regulate the power supply of the microgrid 200 in cooperation with the local generator controllers 206 and the local ESS controllers 210. The microgrid controller 110 may transmit control signals (e.g., instructions) to the local generator controllers 206 and the local ESS controllers 210 to activate (e.g., to bring online), deactivate (to bring offline), or curtail (limit or regulate to a target output) one or more of the DERs 202. Additionally, or alternatively, the microgrid controller 110 may transmit control signals to one or more switches 213 to control a switch state (e.g., an on state or an off state) of the one or more switches 213, for example, to connect one or more DERs 202 to or disconnect one or more DERs 202 from the microgrid 200 (e.g., the power bus 212). The switches 213 may be integrated in one or both interfaces 116 and 118 described in connection with FIG. 1.

In some cases, two or more power buses 212 may be provided. For example, a power bus may be provided to couple one or more power generators 204 to one or more electric storage devices 208 for charging the one or more electric storage devices 208. For example, the microgrid controller 110 may selectively couple a power generator 204 to an electric storage device 208 to charge the electric storage device 208. Thus, the power bus 212 may be part of a power distribution network of the microgrid 200 that may include one or more power buses used to distribute power between loads 108 and/or DERs 202.

The microgrid 200 may include an interface 216 for connecting the microgrid 200 to and disconnecting the microgrid 200 from an electrical power distribution system 218, such as a macrogrid. The electrical power distribution system 218 may include the external controller 104 (e.g., a macrogrid controller), as described in connection with FIG. 1. The external controller 104 may be coupled to the interface 216 for transmitting control signals, such as instructions or requests, to the microgrid controller 110. The interface 216 may include one or more electrical connections used for connecting the microgrid 200 to the electrical power distribution system 218. The interface 216 may include one or more switches or breakers that are controlled by the microgrid controller 110 for connecting the microgrid 200 to and disconnecting the microgrid 200 from the electrical power distribution system 218. For example, the one or more switches or breakers of the interface 216 may connect the power bus 212 (or another system bus) to or disconnect the power bus 212 (or another system bus) from the electrical power distribution system 218. Thus, the microgrid controller 110 may configure the microgrid 200 to operate in a grid-connected mode by connecting the microgrid 200 to the electrical power distribution system 218 or in a stand-alone mode by disconnecting the microgrid 200 from the electrical power distribution system 218.

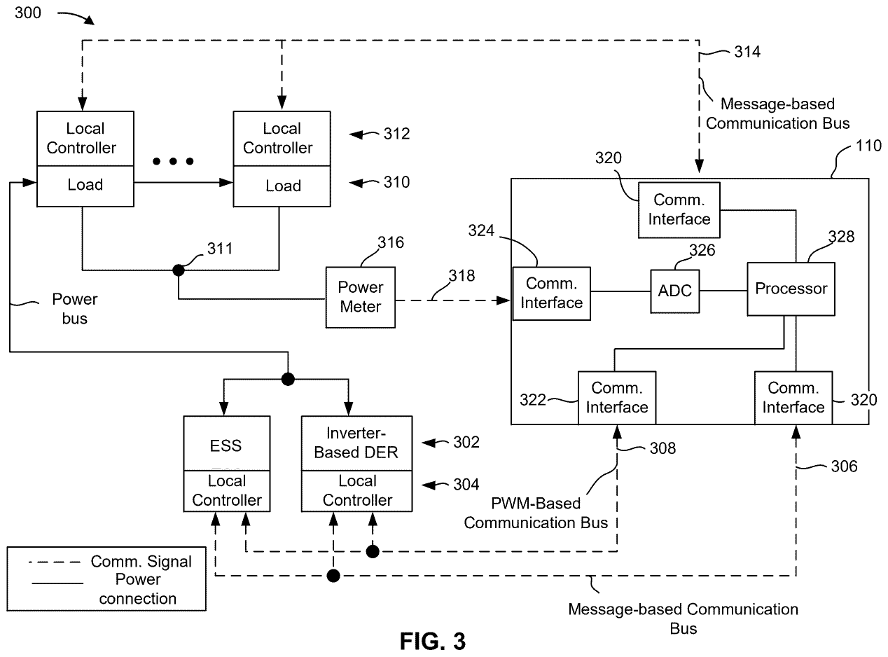

FIG. 3 shows a microgrid 300 according to one or more implementations. The microgrid 300 may include the microgrid controller 110 described in connection with FIGS. 1 and 2. The microgrid 300 may include a plurality of energy resource systems configured to supply power. The plurality of energy resource systems may include inverter-based energy resource systems 302, such as ESSs or other bidirectional inverter-based DERs. In some implementations, the plurality of energy resource systems may include PVs, wind turbines, and/or gensets. The ESS shown in FIG. 3 may correspond to a group of ESSs that are connected as a battery rack. The microgrid 300 may include a plurality of local controllers 304 for the plurality of energy resource systems, as similarly described in connection with FIG. 2. Each local controller 304 may be associated with a respective energy resource system of the plurality of energy resource systems, for obtaining information about the respective energy resource system and controlling the respective energy resource system. The plurality of energy resource systems may include multiple groups or racks of ESSs, each with a respective local controller 304.

The plurality of local controllers 304 may be connected to the microgrid controller 110 by one or more message-based communication buses 306 for exchanging information (e.g., messages) with the microgrid controller 110 and for receiving control signals from the microgrid controller 110. The message-based communication buses 306 may provide a communication interface between the microgrid controller 110 and the local controllers 304. Additionally, the plurality of local controllers 304 may be connected to the microgrid controller 110 by one or more PWM-based communication buses 308 for exchanging information with the microgrid controller 110 and for receiving control signals (e.g., PWM control signals) from the microgrid controller 110. The PWM-based communication bus 308 may provide a fast communication interface between the microgrid controller 110 and the local controllers 304. In other words, the PWM-based communication bus 308 may enable faster communications between the microgrid controller 110 and the local controllers 304 than the message-based communication buses 306.

The plurality of energy resource systems, including the inverter-based energy resource systems 302, may be connected to loads 310 by one or more power buses. Accordingly, the plurality of energy resource systems may provide power directly to the loads 310. Thus, the power buses may be configured to deliver power from the plurality of energy resource systems to one or more loads. In some implementations, the loads 310 may be coupled at a common coupling 311 at which a total load required by the loads 310 can be monitored. The total load may be monitored by measuring a voltage and a current at the common coupling 311. In some implementations, the common coupling 311 is coupled to the power bus. The total load is representative of a sum of all power demanded by the loads 310.

The microgrid 300 may include a plurality of local controllers 312 for the loads 310. Each local controller 312 may associated with a respective load 310, for obtaining information about the respective load 310 and controlling the respective load 310. The plurality of local controllers 312 may be connected to the microgrid controller 110 by one or more message-based communication buses 314 for exchanging information with the microgrid controller 110 and for receiving control signals from the microgrid controller 110. The message-based communication buses 306 and the message-based communication buses 314 may be part of a same communication interface.

The microgrid 300 may include a power meter 316 coupled to the common coupling 311 and configured to measure, at the common coupling 311, one or more load parameters corresponding to a total load required by the loads 310. The one or more load parameters may include voltage and/or current. The power meter 316 may transmit measurement signals representative of measured values of the one or more load parameters to the microgrid controller 110 via a communication interface 318, and the microgrid controller 110 may calculate the total load (e.g., total power) based on the one or more load parameters (e.g., based on the voltage and current). Alternatively, the power meter 316 may calculate the total load (e.g., total power) based on the one or more load parameters, and transmit measured values of the total load to the microgrid controller 110 via the communication interface 318.

The microgrid controller 110 may include a first communication interface 320, a second communication interface 322, a third communication interface 324, an analog-to digital converter (ADC) circuit 326, and a processing circuit 328. Each communication interface may include one or more processors for performing communications according to a respective communication protocol. In some cases, the communication interfaces may share one or more processors.

The first communication interface 320 may be configured to communicate with the energy resource systems, including inverter-based energy resource systems 302, and the loads 310 (e.g., with the local controllers 304 and 312) via the message-based communication buses 306 and 314. For example, the first communication interface 320 may receive load information corresponding to the loads 310, receive energy resource information corresponding to the plurality of energy resource systems, and transmit control messages for controlling an operation of each energy resource system of the plurality of energy resource systems. Thus, the first communication interface 320 may be a message-based communication interface. The first communication interface 320 may interact with the processing circuit 328 for providing received information to the processing circuit 328 or for transmitting information received from the processing circuit 328.

The second communication interface 322 may be configured to communicate with the inverter-based energy resource systems 302 (e.g., with the local controllers 304) via the PWM-based communication bus 308. Thus, the second communication interface 322 may be a PWM-based communication interface.

The third communication interface 324 may be configured to receive measurement signals from the power meter via the communication interface 318. The measurement signals may include the one or more load parameters measured by the power meter 316 or the total load measured by the power meter 316.

The ADC circuit 326 may include one or more ADCs for acquiring samples of the one or more load parameters or the total load. The samples of each load parameter may be provided to the processing circuit 328 for calculating the total load and/or for calculating load transients. The processing circuit 328 may include one or more processors for calculating the total load and/or for calculating load transients. The one or more processors may also evaluate the total load (e.g., the load transients) for detecting fast load transients. The one or more processors may also generate dispatch commands or other control commands based on detecting a fast load transient. The second communication interface 322 may receive the dispatch commands or the other control commands from the processing circuit 328 and generate PWM control signals based on the control commands and a communication protocol (e.g., a PWM protocol). Thus, the second communication interface 322 may include one or more processors for generating the PWM control signals for transmission to the local controllers 304.

In some implementations, the processing circuit 328 may monitor the total load for load transients based on the one or more load parameters measured by the power meter, and detect a fast load transient of the total load that satisfies a transient threshold of one or more transient thresholds. The second communication interface 322 may generate, based on the processing circuit 328 detecting the fast load transient, a PWM control signal, and transmit the PWM control signal to at least one inverter-based energy resource system of the inverter-based energy resource systems 302 to satisfy a transient total load corresponding to the fast load transient.

In some implementations, the processing circuit 328 may obtain a plurality of samples of the total load on a running basis, calculate a load transient of the plurality of samples in a moving window, continually compare the load transient of the plurality of samples in the moving window to the one or more transient thresholds, and detect the load transient of the plurality of samples in the moving window as the fast load transient based on the load transient satisfying a transient threshold of the one or more transient thresholds. Accordingly, the processing circuit 328 may monitor the total load for fast load transients on a continual basis, and initiate PWM commands in real-time in order to promptly satisfy the transient total load. The use of the power meter 316 and the second communication interface 322 bypasses the relatively slow, processing-intensive message-based communication protocol used by the first communication interface 320 for faster response times.

In some implementations, the one or more transient thresholds include a first transient threshold having a positive value corresponding to an increase in the total load, and a second transient threshold having a negative value corresponding to a decrease in the total load. The first transient threshold may be a first predetermined rate-of-change of the total load, and the second transient threshold may be a second predetermined rate-of-change of the total load. The first predetermined rate-of-change and the second predetermined rate-of-change may have the same slope or different slopes. The processing circuit 328 may, based on the fast load transient satisfying the first transient threshold, generate a first PWM command for increasing a power output of the inverter-based energy resource systems 302 to satisfy the transient total load. The second communication interface 322 may generate a corresponding first PWM control signal based on the first PWM command, and transmit the first PWM control signal to the at least one inverter-based energy resource system of the inverter-based energy resource systems 302. Alternatively, the processing circuit 328 may, based on the fast load transient satisfying the second transient threshold, generate a second PWM command for decreasing the power output of the inverter-based energy resource systems 302 to satisfy the transient total load. The second communication interface 322 may generate a corresponding second PWM control signal based on the second PWM command, and transmit the second PWM control signal to the at least one inverter-based energy resource system of the inverter-based energy resource systems 302.

As described above, the inverter-based energy resource systems 302 may be or may include energy storage systems (e.g., BESSs) configured to be charged in a charging state and discharged in a discharging state. Thus, the first PWM control signal may be configured to increase an amount of power discharged from the energy storage systems. For example, additional energy storage systems may be set in the discharging state in order to increase the amount of power discharged from the energy storage systems. In other words, the first PWM control signal may be used to switch one or more of the energy storage systems from the charging state to the discharging state to increase the amount of power discharged from the energy storage systems. The second PWM control signal may be configured to decrease the amount of power discharged from the energy storage systems. For example, energy storage systems may be set in the charging state in order to decrease the amount of power discharged from the energy storage systems. In other words, the second PWM control signal may be used to switch one or more of the energy storage systems from the discharging state into the charging state to decrease the amount of power discharged from the energy storage systems.

In some implementations, the one or more transient thresholds include a first transient threshold having a first positive value corresponding to a first increase in the total load, and a second transient threshold having a second positive value corresponding to a second increase in the total load. In other words, the first transient threshold and the second transient threshold may correspond to different slopes that may require different actions to be performed by the processing circuit 328. Accordingly, the microgrid controller 110 (e.g., via the processing circuit 328 and the second communication interface 322) may, based on the fast load transient satisfying the first transient threshold, generate a first PWM control signal for increasing a power output of the inverter-based energy resource systems 302 by a first amount to satisfy the transient total load, and transmit the first PWM control signal to the at least one inverter-based energy resource system of the inverter-based energy resource systems 302. Alternatively, the microgrid controller 110 may, based on the fast load transient satisfying the second transient threshold, generate a second PWM control signal for increasing the power output of the inverter-based energy resource systems 302 by a second amount to satisfy the transient total load, and transmit the second PWM control signal to the at least one inverter-based energy resource system of the inverter-based energy resource systems 302.

In some implementations, the one or more transient thresholds include a first transient threshold having a first negative value corresponding to a first decrease in the total load, and a second transient threshold having a second negative value corresponding to a second decrease in the total load. In other words, the first transient threshold and the second transient threshold may correspond to different slopes that may require different actions to be performed by the processing circuit 328. Accordingly, the microgrid controller 110 (e.g., via the processing circuit 328 and the second communication interface 322) may, based on the fast load transient satisfying the first transient threshold, generate a first PWM control signal for decreasing a power output of the inverter-based energy resource systems 302 by a first amount to satisfy the transient total load, and transmit the first PWM control signal to the at least one inverter-based energy resource system of the inverter-based energy resource systems 302. Alternatively, the microgrid controller 110 may, based on the fast load transient satisfying the second transient threshold, generate a second PWM control signal for decreasing the power output of the inverter-based energy resource systems 302 by a second amount to satisfy the transient total load, and transmit the second PWM control signal to the at least one inverter-based energy resource system of the inverter-based energy resource systems 302.

While “first” and “second” have been used to describe various transient thresholds and PWM control signals, the above-described configurations may be combined such that any combination or number of transient thresholds and PWM control signals may be used, resulting in more than two (e.g., first, second, third, fourth, etc.) transient thresholds and PWM control signals being implemented in order to quickly assess fast load transients and quickly transmit a corresponding PWM control signal. Accordingly, a transient total load may be addressed in real-time, which would otherwise not be possible using a message-based communication protocol alone.

The microgrid controller 110 may be configured with a fast dispatch mode to dispatch transient loads. During the fast dispatch mode, the microgrid controller 110 may utilize a feed forward control scheme to detect fast transients and dispatch commands to the inverter-based energy resource systems 302. The microgrid controller 110 may predict an effect of a fast transient on the microgrid 300 and proactively adjust the power being supplied/absorbed by the inverter-based energy resource systems 302 to counteract the effect. Accordingly, a response time in addressing transient loads may be improved and a strain on the microgrid 300 reduced.

The microgrid controller 110 may detect fast load transients and control the inverter-based energy resource systems 302 to act as a power consumer or as an energy source to maintain a system bus frequency at a nominal value, thereby ensuring better power quality. The microgrid controller 110 may control the inverter-based energy resource systems 302 to act as a near instantaneous load or energy source in order to quickly satisfy a transient total load. In one aspect of this disclosure, the microgrid controller 110 may control the inverter-based energy resource systems 302 to instantaneously inject power when power is needed by the loads 310 or instantaneously absorb surplus power. Accordingly, the microgrid controller 110 may regulate the power supply such that an exact amount of desired power supply flows in or out of the inverter-based energy resource systems 302 at any given time.

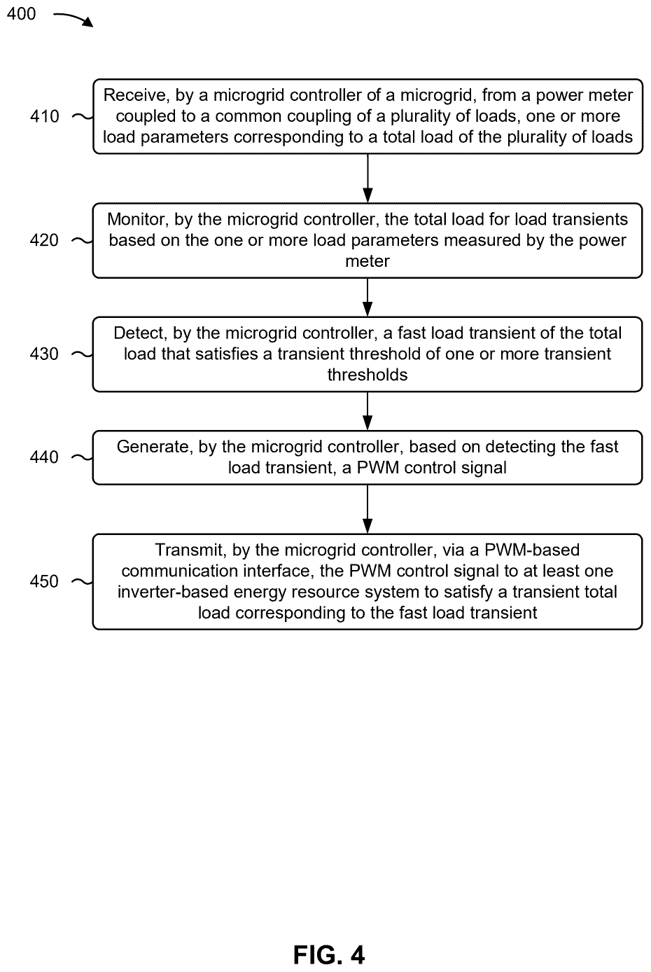

FIG. 4 is a flowchart of an example process 400 associated with a feed forward transient assist mode in a microgrid controller. One or more process blocks of FIG. 4 may be performed by a microgrid controller (e.g., microgrid controller 110). Additionally, or alternatively, one or more process blocks of FIG. 4 may be performed by another device or a group of devices separate from or including the microgrid controller, such as another device or component that is internal or external to a microgrid.

As shown in FIG. 4, process 400 may include receiving, from a power meter coupled to a common coupling of a plurality of loads, one or more load parameters corresponding to a total load of the plurality of loads (block 410). For example, the microgrid controller 110 may receive the one or more load parameters corresponding to a total load of the plurality of loads, as described above.

As further shown in FIG. 4, process 400 may include monitoring the total load for load transients based on the one or more load parameters measured by the power meter (block 420). For example, the microgrid controller 110 may monitor the total load for load transients based on the one or more load parameters measured by the power meter, as described above.

As further shown in FIG. 4, process 400 may include detecting a fast load transient of the total load that satisfies a transient threshold of one or more transient thresholds (block 430). For example, the microgrid controller 110 may detect a fast load transient of the total load that satisfies a transient threshold of one or more transient thresholds, as described above.

As further shown in FIG. 4, process 400 may include generating, based on detecting the fast load transient, a PWM control signal (block 440). For example, the microgrid controller 110 may generate, based on detecting the fast load transient, the PWM control signal, as described above.

As further shown in FIG. 4, process 400 may include transmitting, via a PWM-based communication interface, the PWM control signal to at least one inverter-based energy resource system to satisfy a transient total load corresponding to the fast load transient (block 450). For example, the microgrid controller 110 may transmit, via the PWM-based communication interface, the PWM control signal to at least one inverter-based energy resource system to satisfy the transient total load corresponding to the fast load transient, as described above.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

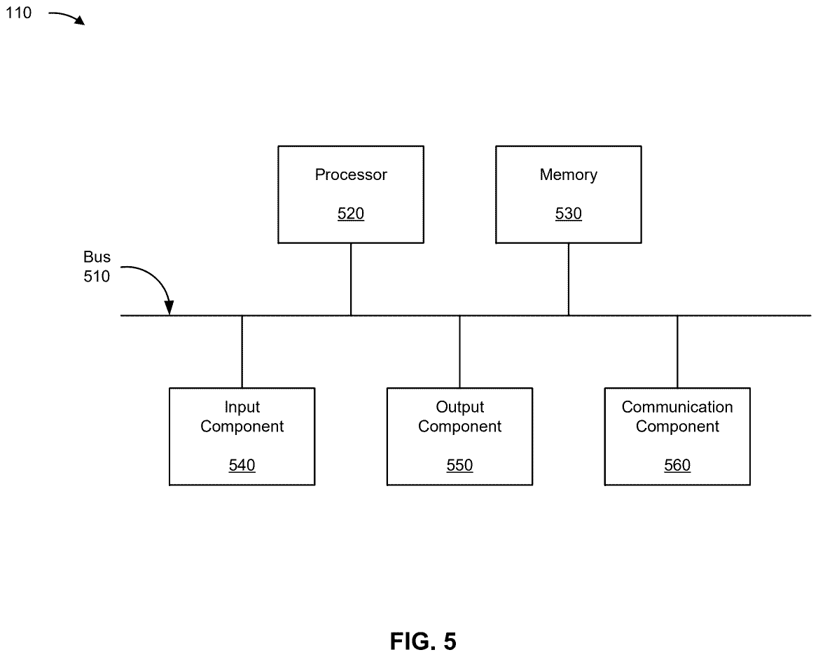

FIG. 5 is a diagram of example components of the microgrid controller 110 associated with a feed forward transient assist mode. The microgrid controller 110 may include a bus 510, a processor 520, a memory 530, an input component 540, an output component 550, and/or a communication component 560.

The bus 510 may include one or more components that enable wired and/or wireless communication among the components of the microgrid controller 110. The bus 510 may couple together two or more components of FIG. 5, such as via operative coupling, communicative coupling, electronic coupling, and/or electric coupling. For example, the bus 510 may include an electrical connection (e.g., a wire, a trace, and/or a lead) and/or a wireless bus.

The processor 520 may include a central processing unit a microprocessor, a controller, a microcontroller, a digital signal processor, a field-programmable gate array, an application-specific integrated circuit, and/or another type of processing component. The processor 520 may be implemented in hardware, firmware, or a combination of hardware and software. The processor 520 may include one or more processors capable of being programmed to perform one or more operations or processes described elsewhere herein. For example, the processor 520 may be part of the processing circuit 328 and/or any of the communication interfaces 320, 322, and 324.

The memory 530 may store information, one or more instructions, and/or software (e.g., one or more software applications) related to the operation of the microgrid controller 110. The memory 530 may include one or more memories that are coupled (e.g., communicatively coupled) to one or more processors (e.g., processor 520), such as via the bus 510. Communicative coupling between a processor 520 and a memory 530 may enable the processor 520 to read and/or process information stored in the memory 530 and/or to store information in the memory 530.

The input component 540 may enable the microgrid controller 110 to receive input, load information, load parameters (e.g., from the power meter 316), generator data, energy storage data, status information, scheduling information, and/or control signals (e.g., control signals from a macrogrid controller). The output component 550 may enable the microgrid controller 110 to provide output, such as one or more control signals for controlling loads, energy storage systems, breakers, switches, and other components associated with the microgrid described herein. The communication component 560 may enable the microgrid controller 110 to communicate with other devices via a wired connection and/or a wireless connection. For example, the communication component 560 may include a receiver, a transmitter, and/or a transceiver. The input component 540, the output component 550, and the communication component 560 may be incorporated into one or more communication interfaces 320, 322, and 324.

The microgrid controller 110 may perform one or more operations or processes described herein. For example, a non-transitory computer-readable medium (e.g., memory 530) may store a set of instructions (e.g., one or more instructions or code) for execution by the processor 520. The processor 520 may execute the set of instructions to perform one or more operations or processes described herein. Execution of the set of instructions, by one or more processors 520, may cause the one or more processors 520 and/or the microgrid controller 110 to perform one or more operations or processes described herein. Hardwired circuitry may be used instead of or in combination with the instructions to perform one or more operations or processes described herein. Additionally, or alternatively, the processor 520 may be configured to perform one or more operations or processes described herein. Thus, implementations described herein are not limited to any specific combination of hardware circuitry and software.

### INDUSTRIAL APPLICABILITY

A microgrid system described herein may include a microgrid controller configured with a fast dispatch mode for handling transient loads in a real-time manner. The fast dispatch mode enables the microgrid controller to improve power management within a power system, such as a microgrid. The fast dispatch mode is especially useful in power systems in which multiple types of loads are added or shed from the power system, resulting in fast changes in the total load within the power system. During the fast dispatch mode, the microgrid controller may utilize a feed forward control scheme to detect fast transients and dispatch commands to inverter-based energy resource systems.

The microgrid controller may detect fast load transients and control inverter-based energy resource systems to act as a power consumer or as an energy source to maintain a system bus frequency at a nominal value, thereby ensuring better power quality. The microgrid controller may control the inverter-based energy resource systems to act as a near-instantaneous load or energy source in order to quickly satisfy a transient total load. In one aspect of this disclosure, the microgrid controller may control the inverter-based energy resource systems to instantaneously inject power when power is needed by the loads, or instantaneously absorb surplus power. Accordingly, the microgrid controller may regulate the power supply such that an exact amount of desired power flows in or out of the energy resource systems at any given time.

What is claimed is:

1. A microgrid system, comprising:
a plurality of energy resource systems configured to supply power to a microgrid, wherein the plurality of energy resource systems includes inverter-based energy resource systems;
a plurality of loads coupled at a common coupling;
one or more power buses configured to deliver power from the plurality of energy resource systems to the plurality of loads;
a power meter coupled to the common coupling and configured to measure, at the common coupling, one or more load parameters corresponding to a total load required by the plurality of loads; and
a microgrid controller configured to:
communicate with the plurality of energy resource systems and the plurality of loads via a first communication interface, the first communication interface being a message-based communication interface,
communicate with the inverter-based energy resource systems via a second communication interface, the second communication interface being a pulse-width modulation (PWM)-based communication interface,
monitor the total load for load transients based on the one or more load parameters measured by the power meter,
detect a fast load transient of the total load that satisfies a transient threshold of one or more transient thresholds,
generate, based on detecting the fast load transient, a PWM control signal, and
transmit, via the second communication interface, the PWM control signal to at least one inverter-based energy resource system of the inverter-based energy resource systems to satisfy a transient total load corresponding to the fast load transient.

2. The microgrid system of claim 1, wherein the one or more load parameters include voltage and current, wherein the power meter or the microgrid controller is configured to calculate the total load based on the voltage and the current.

3. The microgrid system of claim 1, wherein the microgrid controller is configured to:
obtain a plurality of samples of the total load on a running basis,
calculate a load transient of the plurality of samples in a moving window,
continually compare the load transient of the plurality of samples in the moving window to the one or more transient thresholds, and
detect the load transient of the plurality of samples in the moving window as the fast load transient based on the load transient satisfying the transient threshold of the one or more transient thresholds.

4. The microgrid system of claim 1, wherein the one or more transient thresholds include a first transient threshold having a positive value corresponding to an increase in the total load, and a second transient threshold having a negative value corresponding to a decrease in the total load,
wherein the microgrid controller is configured to:
based on the fast load transient satisfying the first transient threshold, generate a first PWM control signal for increasing a power output of the inverter-based energy resource systems to satisfy the transient total load, and transmit the first PWM control signal to the at least one inverter-based energy resource system of the inverter-based energy resource systems, and
based on the fast load transient satisfying the second transient threshold, generate a second PWM control signal for decreasing the power output of the inverter-based energy resource systems to satisfy the transient total load, and transmit the second PWM control signal to the at least one inverter-based energy resource system of the inverter-based energy resource systems.

5. The microgrid system of claim 4, wherein the first transient threshold is a first predetermined rate-of-change of the total load, and
wherein the second transient threshold is a second predetermined rate-of-change of the total load.

6. The microgrid system of claim 4, wherein the inverter-based energy resource systems are energy storage systems configured to be charged in a charging state and discharged in a discharging state,
wherein the first PWM control signal is configured to increase an amount of power discharged from the energy storage systems, and
wherein the second PWM control signal is configured to decrease the amount of power discharged from the energy storage systems.

7. The microgrid system of claim 6, wherein the first PWM control signal is configured to switch one or more of the energy storage systems from the charging state into the discharging state to increase the amount of power discharged from the energy storage systems.

8. The microgrid system of claim 6, wherein the second PWM control signal is configured to switch one or more of the energy storage systems from the discharging state into the charging state to decrease the amount of power discharged from the energy storage systems.

9. The microgrid system of claim 1, wherein the one or more transient thresholds include a first transient threshold having a first positive value corresponding to a first increase in the total load, and a second transient threshold having a second positive value corresponding to a second increase in the total load,
wherein the microgrid controller is configured to:
based on the fast load transient satisfying the first transient threshold, generate a first PWM control signal for increasing a power output of the inverter-based energy resource systems by a first amount to satisfy the transient total load, and transmit the first PWM control signal to the at least one inverter-based energy resource system of the inverter-based energy resource systems, and
based on the fast load transient satisfying the second transient threshold, generate a second PWM control signal for increasing the power output of the inverter-based energy resource systems by a second amount to satisfy the transient total load, and transmit the second PWM control signal to the at least one inverter-based energy resource system of the inverter-based energy resource systems.

10. The microgrid system of claim 1, wherein the one or more transient thresholds include a first transient threshold having a first negative value corresponding to a first decrease in the total load, and a second transient threshold having a second negative value corresponding to a second decrease in the total load,
wherein the microgrid controller is configured to:
based on the fast load transient satisfying the first transient threshold, generate a first PWM control signal for decreasing a power output of the inverter-based energy resource systems by a first amount to satisfy the transient total load, and transmit the first PWM control signal to the at least one inverter-based energy resource system of the inverter-based energy resource systems, and
based on the fast load transient satisfying the second transient threshold, generate a second PWM control signal for decreasing the power output of the inverter-based energy resource systems by a second amount to satisfy the transient total load, and transmit the second PWM control signal to the at least one inverter-based energy resource system of the inverter-based energy resource systems.

11. The microgrid system of claim 1, wherein the microgrid controller is configured to, via the first communication interface, receive load information corresponding to the plurality of loads, receive energy resource information corresponding to the plurality of energy resource systems, and transmit control messages for controlling an operation of each energy resource system of the plurality of energy resource systems.

12. The microgrid system of claim 11, wherein the first communication interface is a transmission control protocol (TCP) communication bus.

13. The microgrid system of claim 11, wherein the microgrid controller is configured to transmit and receive messages via the first communication interface according to a Modbus communication protocol.

14. A microgrid controller of a microgrid, comprising:
a message-based communication interface configured to enable message-based communications with a plurality of loads connected to the microgrid and a plurality of energy resource systems connected to the microgrid, wherein the plurality of energy resource systems includes inverter-based energy resource systems;
a pulse-width modulation (PWM)-based communication interface configured to transmit PWM commands to the inverter-based energy resource systems;
a third communication interface configured to receive, from a power meter coupled to a common coupling of the plurality of loads, one or more load parameters corresponding to a total load required by the plurality of loads;
one or more memories; and
one or more processors, coupled to the one or more memories, configured to:
monitor the total load for load transients based on the one or more load parameters measured by the power meter, detect a fast load transient of the total load that satisfies a transient threshold of one or more transient thresholds,
generate, based on detecting the fast load transient, a PWM control signal, and
transmit, via the PWM-based communication interface, the PWM control signal to at least one inverter-based energy resource system of the inverter-based energy resource systems to satisfy a transient total load corresponding to the fast load transient.

15. The microgrid controller of claim 14, wherein the one or more load parameters include voltage and current, or power.

16. The microgrid controller of claim 14, wherein the one or more processors are configured to:
obtain a plurality of samples of the total load on a running basis,
calculate a load transient of the plurality of samples in a moving window,
continually compare the load transient of the plurality of samples in the moving window to the one or more transient thresholds, and
detect the load transient of the plurality of samples in the moving window as the fast load transient based on the load transient satisfying the transient threshold of the one or more transient thresholds.

17. The microgrid controller of claim 14, wherein the one or more transient thresholds include a first transient threshold having a positive value corresponding to an increase in the total load, and a second transient threshold having a negative value corresponding to a decrease in the total load,
wherein the one or more processors are configured to:
based on the fast load transient satisfying the first transient threshold, generate a first PWM control signal for increasing a power output of the inverter-based energy resource systems to satisfy the transient total load, and transmit the first PWM control signal to the at least one inverter-based energy resource system, and
based on the fast load transient satisfying the second transient threshold, generate a second PWM control signal for decreasing the power output of the inverter-based energy resource systems to satisfy the transient total load, and transmit the second PWM control signal to the at least one inverter-based energy resource system.

18. The microgrid controller of claim 17, wherein the first transient threshold is a first predetermined rate-of-change of the total load, and
wherein the second transient threshold is a second predetermined rate-of-change of the total load.

19. The microgrid controller of claim 17, wherein the inverter-based energy resource systems are energy storage systems configured to be charged in a charging state and discharged in a discharging state,
wherein the first PWM control signal is configured to increase an amount of power discharged from the energy storage systems, and
wherein the second PWM control signal is configured to decrease the amount of power discharged from the energy storage systems.

20. A method for controlling assets of a microgrid, comprising:
receiving, by a microgrid controller of the microgrid, from a power meter coupled to a common coupling of a plurality of loads, one or more load parameters corresponding to a total load of the plurality of loads;
monitoring, by the microgrid controller, the total load for load transients based on the one or more load parameters measured by the power meter;
detecting, by the microgrid controller, a fast load transient of the total load that satisfies a transient threshold of one or more transient thresholds;
generating, by the microgrid controller, based on detecting the fast load transient, a pulse-width modulation (PWM) control signal; and
transmitting, by the microgrid controller, via a PWM-based communication interface, the PWM control signal to at least one inverter-based energy resource system of the inverter-based energy resource systems to satisfy a transient total load corresponding to the fast load transient.
